(19) United States
(12) Patent Application Publication
(10) Pub. No.: US 2015/0380605 A1
(43) Pub. Date: Dec. 31, 2015

(54) SEMICONDUCTOR STRUCTURE

(71) Applicant: Genesis Photonics Inc., Tainan City (TW)

(72) Inventors: Chi-Hao Cheng, Tainan City (TW); Chi-Feng Huang, Tainan City (TW); Sheng-Han Tu, Tainan City (TW)

(21) Appl. No.: 14/707,010

(22) Filed: May 8, 2015

(30) Foreign Application Priority Data
Jun. 30, 2014 (TW) 103122543

(51) Int. Cl. H01L 33/12; H01L 33/32

(52) U.S. Cl. CPC H01L 33/12; H01L 33/325

(57) ABSTRACT

A semiconductor structure includes a substrate, a first un-doped semiconductor layer, a second un-doped semiconductor layer and at least one doped insertion layer. The first un-doped semiconductor layer is disposed on the substrate. The second un-doped semiconductor layer is disposed on the first un-doped semiconductor layer.

The doped insertion layer is disposed between the first un-doped semiconductor layer and the second un-doped semiconductor layer. A chemical formula of the doped insertion layer is InₓAl_{y}Ga_{1-x-y}N, wherein 0≦x≦1, 0≦y≦1.

### CROSS-REFERENCE TO RELATED APPLICATION

This application claims the priority benefit of Taiwan application serial no. 103122543, filed on Jun. 30, 2014. The entirety of the above-mentioned patent application is hereby incorporated by reference herein and made a part of this specification.

### BACKGROUND OF THE INVENTION

1. Field of the Invention

The invention relates to a semiconductor structure, and particularly relates to a semiconductor structure having a stress buffer insertion layer.

2. Description of Related Art

With the progress of semiconductor technologies, a light emitting diode (LED) now has advantages of high luminance, low power consumption, compactness, low driving voltage, being mercury free, and so forth. Therefore, the LED has been extensively applied in the field of displays and illumination. In general, an LED chip is fabricated by using a broad band-gap semiconductor material, such as gallium nitride (GaN). However, in addition to the difference in thermal expansion coefficient and chemical properties, the difference between the lattice constant of GaN and that of a hetero-substrate cannot be ignored. Hence, due to lattice mismatch, GaN grown on the hetero-substrate undergoes lattice dislocation, and the lattice dislocation extends toward a thickness direction of the GaN layer. Further, because of lattice mismatch between GaN and the hetero-substrate, the material of GaN relative to the hetero-substrate will create great structural stress. As the growth thickness becomes thicker, the stress accumulated becomes greater. When exceeding a threshold value, the material layer will be unable to support the stress, and must deform to release the stress. Besides, the material may have a bowing modulation or a cracking phenomenon during a growth process thereof. As such, the lattice dislocation not only causes crystal growth defects which reduce the light emitting efficiency of the LED and shortens lifetime, it also can not grow very thick GaN.

### SUMMARY OF THE INVENTION

The invention is directed to a semiconductor structure, which reduces lattice dislocation extending in a thickness direction and mitigates a bowing modulation of material during a growth process thereof.

The invention provides a semiconductor structure including a substrate, a first un-doped semiconductor layer, a second un-doped semiconductor layer and at least one doped insertion layer. The first un-doped semiconductor layer is disposed on the substrate. The second un-doped semiconductor layer is disposed on the first un-doped semiconductor layer. The doped insertion layer is disposed between the first un-doped semiconductor layer and the second un-doped semiconductor layer. A chemical formula of the doped insertion layer is InₓAl_{y}Ga_{1-x-y}N, where 0≦x≦1, 0≦y≦1.

In an embodiment of the invention, the at least one doped insertion layer is a plurality of doped insertion layers, and a spacing distance is spaced between any two adjacent doped insertion layers.

In an embodiment of the invention, a thickness of each of the doped insertion layers is different.

In an embodiment of the invention, the first un-doped semiconductor layer and the second un-doped semiconductor layer are respectively a group III-V element semiconductor layer.

In an embodiment of the invention, the group III-V element semiconductor layer includes a GaN layer, an AlInGaN layer, or a GaAs layer.

In an embodiment of the invention, a formation temperature of the doped insertion layer is lower than a formation temperature of the first un-doped semiconductor layer and a formation temperature of the second un-doped semiconductor layer.

In an embodiment of the invention, the formation temperature of the first un-doped semiconductor layer is lower than the formation temperature of the second un-doped semiconductor layer.

In an embodiment of the invention, the formation temperature of the doped insertion layer is between 600° C. and 1100° C.

In an embodiment of the invention, the formation temperature of the first un-doped semiconductor layer is between 800° C. and 1200° C.

In an embodiment of the invention, the formation temperature of the second un-doped semiconductor layer is between 900° C. and 1300° C.

In an embodiment of the invention, a thickness of the doped insertion layer is between 1 nm and 500 nm.

In an embodiment of the invention, the doped insertion layer has a doped element, and the doped element is a group IV element.

In an embodiment of the invention, the group IV element includes carbon, germanium or silicon.

In an embodiment of the invention, a doping concentration of the doped insertion layer is 5×10¹⁶/cm³ and 5×10²⁰/cm³.

According to the above descriptions, in the semiconductor structure of the invention, the doped insertion layer is configured between the first un-doped semiconductor layer and the second un-doped semiconductor layer to reduce lattice dislocation extending in a thickness direction and decrease a defect density, and accordingly mitigate a bowing modulation of material during a growth process thereof, so as to improve the quality of the whole semiconductor structure.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a semiconductor structure according to an embodiment of the invention.

FIG. 2 is a cross-sectional view of a semiconductor structure according to another embodiment of the invention.

### DESCRIPTION OF EMBODIMENTS

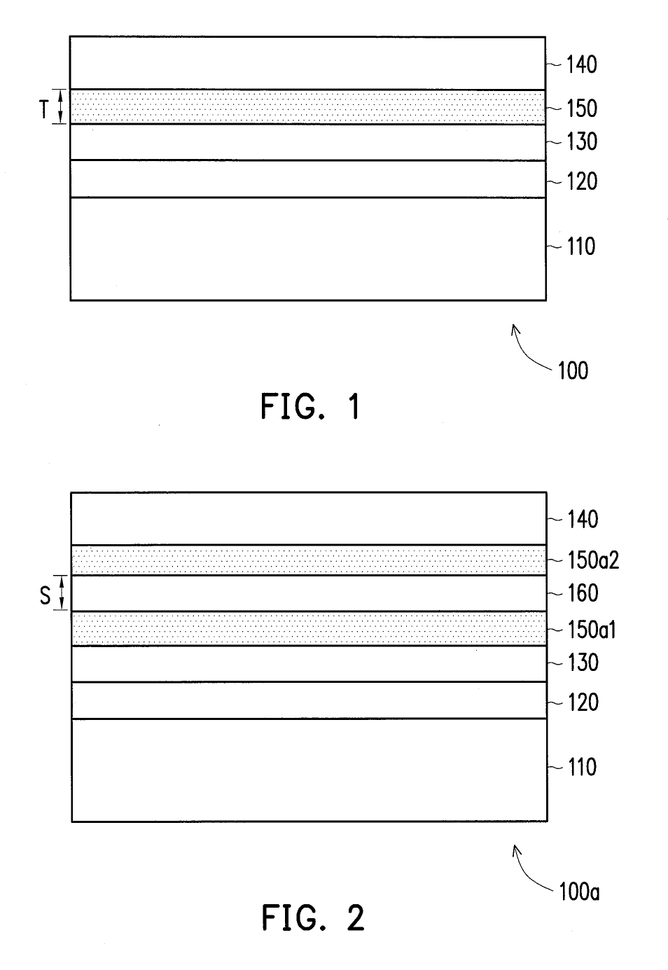

FIG. 1 is a cross-sectional view of a semiconductor structure according to an embodiment of the invention. Referring to FIG. 1, in the present embodiment, the semiconductor structure 100 includes a substrate 110, a first un-doped semiconductor layer 130, a second un-doped semiconductor layer 140 and a doped insertion layer 150. The first un-doped semiconductor layer 130 is disposed on the substrate 110. The second un-doped semiconductor layer 140 is disposed on the first un-doped semiconductor layer 130. The doped insertion layer 150 is disposed between the first un-doped semiconductor layer 130 and the second un-doped semiconductor layer 140. The semiconductor layer 100 of the present embodiment may further include a buffer layer 120 disposed between the substrate 110 and the first un-doped semiconductor layer 130, so as to reduce a stress between the first un-doped semiconductor layer 130 and the substrate 110.

In detail, a material of the substrate 110 of the present embodiment is, for example, silicon, sapphire, silicon carbide, gallium arsenide, or aluminium nitride, though the invention is not limited thereto. The first un-doped semiconductor layer 130 is, for example, a GaN layer, an AlInGaN layer, a GaAs layer or other group III-V element semiconductor layer. The first un-doped semiconductor layer 130 can be a single-layer structure layer or a multi-layer structure layer, which is not limited by the invention. The second un-doped semiconductor layer 140 is, for example, a GaN layer, an AlInGaN layer, a GaAs layer or other group III-V element semiconductor layer. The second un-doped semiconductor layer 140 can be a single-layer structure layer or a multi-layer structure layer. In the present embodiment, the first un-doped semiconductor layer 130 and the second un-doped semiconductor layer 140 are, for example, the single-layer GaN layer, though the invention is not limited thereto.

To be specific, a formation temperature of the doped insertion layer 150 of the present embodiment is lower than a formation temperature of the first un-doped semiconductor layer 130 and a formation temperature of the second un-doped semiconductor layer 140, and the formation temperature of the first un-doped semiconductor layer 130 is lower than the formation temperature of the second un-doped semiconductor layer 140. The formation temperature of the doped insertion layer 150 is preferably between 600° C. and 1100° C., the formation temperature of the first un-doped semiconductor layer 130 is preferably between 800° C. and 1200° C., and the formation temperature of the second un-doped semiconductor layer 140 is between 900° C. and 1300° C. Since the formation temperature of the doped insertion layer 150 is the lowest, the element doped therein is not liable to dissociate, which can be used for adjusting a lattice constant of the doped insertion layer 150, so as to effectively decrease a stress generated during a growth process of the semiconductor structure 100.

Moreover, a chemical formula of the doped insertion layer 150 is InₓAl_{y}Ga_{1-x-y}N, where 0≦x≦1 and 0≦y≦1, and those skilled in the art can select contents of the growing x, y according to an actual requirement, though the invention is not limited thereto. Preferably, the chemical formula of the doped insertion layer 150 is InAlGaN, and a thickness T of the doped insertion layer 150 is preferably between 1 nm and 500 nm. Moreover, in order to vary the lattice constant of a local area, the doped insertion layer 150 of the present embodiment may also have a doped element, where the doped element is, for example, a group IV element, and the the group IV element includes carbon, germanium or silicon. Preferably, the doped element is carbon, and a doping concentration of the doped insertion layer 150 is 5×10¹⁶/cm³ and 5×10²⁰/cm³.

In the semiconductor structure 100 of the present embodiment, since the doped insertion layer 150 is disposed between the first un-doped semiconductor layer 130 and the second un-doped semiconductor layer 140, the doped insertion layer 150 can be used to block a lattice dislocation formed during growth of the first un-doped semiconductor layer 130, such that the lattice dislocation cannot continually grow upwards, and the defect density is decreased, so as to improve the quality of the whole semiconductor structure 100. Moreover, in the semiconductor structure 100 of the present embodiment, the lattice constant of the doped insertion layer 150 can be adjusted by doping the group IV elements with different atom sizes to the doped insertion layer 150, where the smaller doped atoms lead to decrease of the lattice constant of the local area, and the larger doped atoms lead to increase of the lattice constant of the local area, such that the stress generated during growth of the first un-doped semiconductor layer 130 can be adjusted, so as to avoid the bowing modulation of the second un-doped semiconductor layer 140 occurred during the growth process.

It should be noticed that reference numbers of the components and a part of contents of the aforementioned embodiment are also used in the following embodiment, where the same reference numbers denote the same or like components, and descriptions of the same technical contents are omitted. The aforementioned embodiment can be referred for descriptions of the omitted parts, and detailed descriptions thereof are not repeated in the following embodiment.

FIG. 2 is a cross-sectional view of a semiconductor structure according to another embodiment of the invention. Referring to FIG. 1 and FIG. 2, the semiconductor structure 100a of the present embodiment is similar to the semiconductor structure 100 of FIG. 1, and a main difference there between is that the doped insertion layer of the semiconductor structure 100a of the present embodiment is a plurality of doped insertion layers (two doped insertion layers 150a1 and 150a2 are illustrated, though the invention is not limited thereto), and the semiconductor structure 100a of the present embodiment further includes a third un-doped semiconductor layer 160. As shown in FIG. 2, the doped insertion layers 150a1 and 150a2 are located between the first un-doped semiconductor layer 130, the second un-doped semiconductor layer 140 and the third un-doped semiconductor layer 160, where a spacing distance S (which is a thickness of the third un-doped semiconductor layer 160) is spaced between the doped insertion layers 150a1 and 150a2, and the thickness of the doped insertion layers 150a1 and 150a2 can be different. In this way, by configuring the doped insertion layers 150a1 and 150a2, extending of the lattice dislocation along the thickness direction is effectively reduced, and the defect density is decreased, so as to improve the quality of the whole semiconductor structure 100a.

In summary, in the semiconductor structure of the invention, the doped insertion layer is configured between the first un-doped semiconductor layer and the second un-doped semiconductor layer to reduce lattice dislocation extending in a thickness direction and decrease a defect density, and accordingly mitigate a bowing modulation of material during a growth process thereof, so as to improve the quality of the whole semiconductor structure.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A semiconductor structure, comprising:
a substrate;
a first un-doped semiconductor layer, disposed on the substrate;
a second un-doped semiconductor layer, disposed on the first un-doped semiconductor layer; and
at least one doped insertion layer, disposed between the first un-doped semiconductor layer and the second un-doped semiconductor layer, wherein a chemical formula of the doped insertion layer is InₓAl_{y}Ga_{1-x-y}N, wherein 0≦x≦1, 0≦y≦1.

2. The semiconductor structure as claimed in claim 1, wherein the at least one doped insertion layer is a plurality of doped insertion layers, and a spacing distance is spaced between any two adjacent doped insertion layers.

3. The semiconductor structure as claimed in claim 2, wherein a thickness of each of the doped insertion layers is different.

4. The semiconductor structure as claimed in claim 1, wherein the first un-doped semiconductor layer and the second un-doped semiconductor layer are respectively a group III-V element semiconductor layer.

5. The semiconductor structure as claimed in claim 4, wherein the group element semiconductor layer comprises a GaN layer, an AlInGaN layer, or a GaAs layer.

6. The semiconductor structure as claimed in claim 1, wherein a formation temperature of the doped insertion layer is lower than a formation temperature of the first un-doped semiconductor layer and a formation temperature of the second un-doped semiconductor layer.

7. The semiconductor structure as claimed in claim 6, wherein the formation temperature of the first un-doped semiconductor layer is lower than the formation temperature of the second un-doped semiconductor layer.

8. The semiconductor structure as claimed in claim 6, wherein the formation temperature of the doped insertion layer is between 600° C. and 1100° C.

9. The semiconductor structure as claimed in claim 6, wherein the formation temperature of the first un-doped semiconductor layer is between 800° C. and 1200° C.

10. The semiconductor structure as claimed in claim 6, wherein the formation temperature of the second un-doped semiconductor layer is between 900° C. and 1300° C.

11. The semiconductor structure as claimed in claim 1, wherein a thickness of the doped insertion layer is between 1 nm and 500 nm.

12. The semiconductor structure as claimed in claim 1, wherein the doped insertion layer has a doped element, and the doped element is a group IV element.

13. The semiconductor structure as claimed in claim 12, wherein the group IV element comprises carbon, germanium or silicon.

14. The semiconductor structure as claimed in claim 12, wherein a doping concentration of the doped insertion layer is 5×10¹⁶/cm³ and 5×10²⁰/cm³.
